(19) United States
(12) Patent Application Publication
(10) Pub. No.: US 2026/0032971 A1
(43) Pub. Date: Jan. 29, 2026

(54) Integrated Magnetic Circuit for Magnetoresistive Transistor

(71) Applicant: International Business Machines Corporation, Armonk, NY (US)

(72) Inventors: Lorenzo ROCCHINO, Rueschlikon (CH); Bogdan Cezar ZOTA, Rueschlikon (CH); Bernd W. GOTSMANN, Horgen (CH); Federico BALDUINI, Zurich (CH); Heinz SCHMID, Waedenswil (CH)

(21) Appl. No.: 18/773,792

(22) Filed: Jul. 16, 2024

(51) Int. Cl. H10D 48/00; H10D 64/60

(52) U.S. Cl. CPC H10D 48/385; H10D 64/608

(57) ABSTRACT

A magnetoresistive device is provided comprising an active channel comprises an extremely large magnetoresistance (XMR) material. A gate electrode surrounds the active channel, wherein the gate electrode has a first portion on one side of the active channel and a second portion on the opposite side of the active channel. An insulating spacer electrically isolates the active channel from the gate electrode. Electrical current through the gate electrode generates and focuses a magnetic field applied to the active channel.

### BACKGROUND

The disclosure relates generally to semiconductor devices, and more specifically to magnetoresistive transistors.

Electronic transistors such as Field Effect Transistors (FET) are a fundamental building block of integrated circuits. Low-noise amplifiers (LNAs) are electronic components that amplify very low-power signals without significantly degrading the signal-to-noise ratio. Scalability of quantum computers beyond a few hundred qubits, with regards to the classical electronics that are required to read qubits, limits the power consumption of LNAs due to the limited cooling power in cryogenic systems. The concept of ultra-low power cryogenic LNAs has been actively researched. When LNAs operate at extremely low power levels, the noise temperature degrades because the gain of an active component in the LNA decreases. Very large quantum computers may require LNAs operating at <<1 mW, which is not possible at high gain/low noise with current LNA technology.

### SUMMARY

An illustrative embodiment provides a magnetoresistive device comprising an active channel comprises an extremely large magnetoresistance (XMR) material. A gate electrode surrounds the active channel, wherein the gate electrode has a first portion on one side of the active channel and a second portion on the opposite side of the active channel. An insulating spacer electrically isolates the active channel from the gate electrode. Electrical current through the gate electrode focuses and amplifies a magnetic field generated at the active channel.

### BRIEF DESCRIPTION OF THE DRAWINGS

FIG. 1 depicts a generalized magnetoresistive transistor illustrating the operating principles of the illustrative embodiments;

FIG. 2 depicts a top perspective view of a magnetoresistive device in accordance with an illustrative embodiment;

FIG. 3 depicts a cross-section view of the magneto resistive device in accordance with an illustrative embodiment;

FIG. 4 depicts a diagram illustrating magnetic field focusing in accordance with an illustrative embodiment;

FIG. 5 depicts a graph of magnetoresistance versus magnetic field strength for different temperatures with which the illustrative embodiments may be implemented;

FIG. 6 depicts a graph illustrating resistance versus temperature for a superconductive material with which the illustrative embodiments may be implemented;

FIG. 7 depicts a hysteresis graph of a ferromagnetic material with which the illustrative embodiments may be implemented;

FIGS. 8A-8L illustrate the deposition of the substrate and superconductive gate electrode and the patterning of the superconductive gate electrode for a magnetoresistive device in accordance with an illustrative embodiment;

FIGS. 9A-9G illustrate the deposition and patterning of the gold contacts for a magnetoresistive device in accordance with an illustrative embodiment; and

FIGS. 10A-10H illustrate the deposition of the active channel and cap for a magnetoresistive device in accordance with an illustrative embodiment.

### DETAILED DESCRIPTION

A magnetoresistive device comprises an active channel comprises an extremely large magnetoresistance (XMR) material. A gate electrode surrounds the active channel, wherein the gate electrode has a first portion on one side of the active channel and a second portion on the opposite side of the active channel. An insulating spacer electrically isolates the active channel from the gate electrode. As a result, the illustrative embodiments provide a technical effect wherein electrical current through the gate electrode generates and focuses a magnetic field applied to the active channel.

In the illustrative embodiments, the magnetoresistive device may further comprise a ferromagnetic buried layer under the active channel and gate electrode; an insulating layer that electrically isolates the ferromagnetic buried layer from the active channel and gate electrode; and a ferromagnetic cap over the active channel and gate electrode, wherein the ferromagnetic cap and ferromagnetic buried layer form a ferromagnetic loop around the gate electrode. As a result, the illustrative embodiments provide a technical effect of providing a closed ferromagnetic loop around the gate electrode.

In the illustrative embodiments the gate electrode may comprise a superconductive material. As a result, the illustrative embodiments provide a technical effect of providing a superconducting gate electrode.

In the illustrative embodiments the superconductive material may comprise niobium nitride. As a result, the illustrative embodiments provide a technical effect of making a superconductive gate electrode from niobium nitride.

In the illustrative embodiments the XMR material may comprise a Weyl or Dirac semimetal. As a result, the illustrative embodiments provide a technical effect of providing a Weyl or Dirac semimetal active channel to provide extremely large magnetoresistance.

In the illustrative embodiments the Weyl or Dirac semimetal may comprise one of niobium phosphide, graphene, molybdenum phosphide (MoP), tantalum arsenide (TaAs), or cadmium arsenide (Cd3As2).

In the illustrative embodiments the gate electrode wraps around the active channel in a common plane to form a double gate configuration flanking the active channel. As a result, the illustrative embodiments provide a technical effect of providing a double gate configuration that surrounds the active channel to focus and amplify the magnetic field.

A magnetoresistive device comprises a superconductive gate electrode folded into a double gate configuration within a plane. An extremely large magnetoresistance (XMR) channel is positioned in the plane between a first portion and a second portion of the double gate configuration. A ferromagnetic loop comprising a ferromagnetic buried layer under the superconductive gate electrode and XMR channel and a ferromagnetic cap over the superconductive gate electrode and XMR channel. As a result, the illustrative embodiments provide a technical effect wherein electrical current through the superconductive gate electrode generates and focuses a magnetic field applied to the XMR channel.

In the illustrative embodiments the magnetoresistive device may further comprise an insulating spacer that electrically isolates the superconductive gate electrode, XMR channel, and ferromagnetic cap from each other. As a result, the illustrative embodiments provide a technical effect of electrical isolating the superconductive gate electrode, XMR channel, and ferromagnetic cap to prevent shorting between them.

In the illustrative embodiments the superconductive material may comprise niobium nitride. As a result, the illustrative embodiments provide a technical effect of making a superconductive gate electrode from niobium nitride.

In the illustrative embodiments the XMR material may comprise a Weyl or Dirac semimetal. As a result, the illustrative embodiments provide a technical effect of providing a Weyl or Dirac semimetal active channel to provide extremely large magnetoresistance.

In the illustrative embodiments the Weyl or Dirac semimetal may comprise one of niobium phosphide, graphene, molybdenum phosphide (MoP), tantalum arsenide (TaAs), or cadmium arsenide (Cd3As2).

A magnetoresistive device comprises a gate electrode. An extremely large magnetoresistance (XMR) channel is proximal to the gate electrode. A ferromagnetic loop surrounds the gate electrode. As a result, the illustrative embodiments provide a technical effect wherein electrical current through the gate electrode generates and focuses a magnetic field applied to the XMR channel.

In the illustrative embodiments the gate electrode may comprise a superconductive material. As a result, the illustrative embodiments provide a technical effect of providing a superconducting gate electrode.

In the illustrative embodiments the superconductive material may comprise niobium nitride. As a result, the illustrative embodiments provide a technical effect of making a superconductive gate electrode from niobium nitride.

In the illustrative embodiments the XMR channel may comprise a Weyl or Dirac semimetal. As a result, the illustrative embodiments provide a technical effect of providing a Weyl or Dirac semimetal active channel to provide extremely large magnetoresistance.

In the illustrative embodiments the Weyl or Dirac semimetal may comprise one of niobium phosphide, graphene, molybdenum phosphide (MoP), tantalum arsenide (TaAs), or cadmium arsenide (Cd3As2).

In the illustrative embodiments the gate electrode wraps around the XMR channel in a common plane to form a double gate configuration flanking the XMR channel. As a result, the illustrative embodiments provide a technical effect of providing a double gate configuration that surrounds the XMR channel to focus and amplify the magnetic field.

In the illustrative embodiments the ferromagnetic loop comprises a ferromagnetic buried layer under the gate electrode and a ferromagnetic cap over the gate electrode. As a result, the illustrative embodiments provide a technical effect of closing a ferromagnetic loop around the gate electrode.

In the illustrative embodiments the XMR channel fills a gap in the ferromagnetic cap. As a result, the illustrative embodiments provide a technical effect of completing the ferromagnetic loop with XMR material.

The illustrative embodiments recognize and take into account that focusing the magnetic field in a magnetic-based device is essential to prevent losses and interferences between neighboring devices. At a macroscopic level, this focusing of the magnetic field is typically accomplished by using coils to generate the magnetic field inside a ferromagnetic loop. However, there is no real equivalent to such coils available at the micro/nano level.

The illustrative embodiments also recognize and take into account that the magnetic field can be relocated where an active XMR (extremely large magnetoresistance) material is placed, thus enhancing the resistivity modulation.

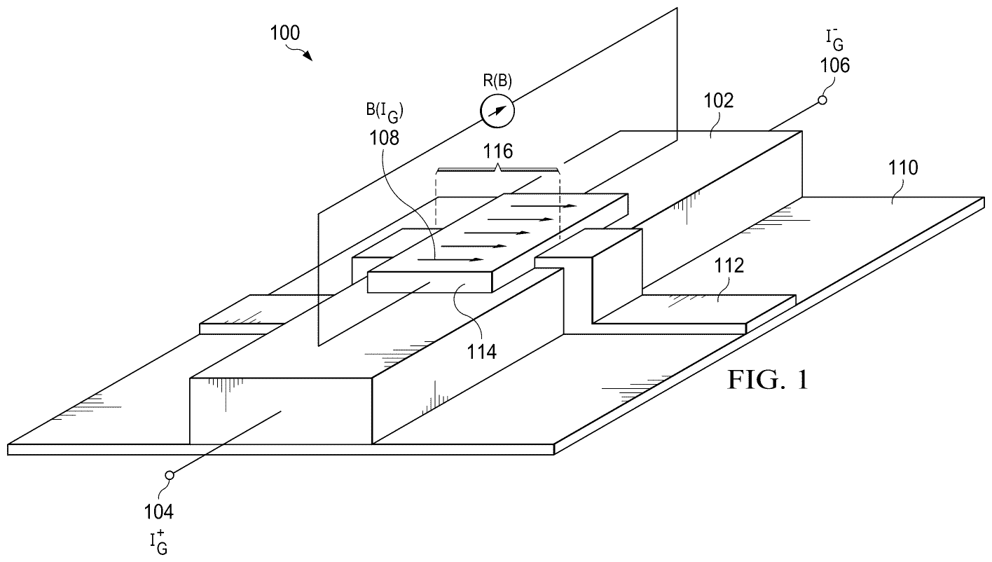

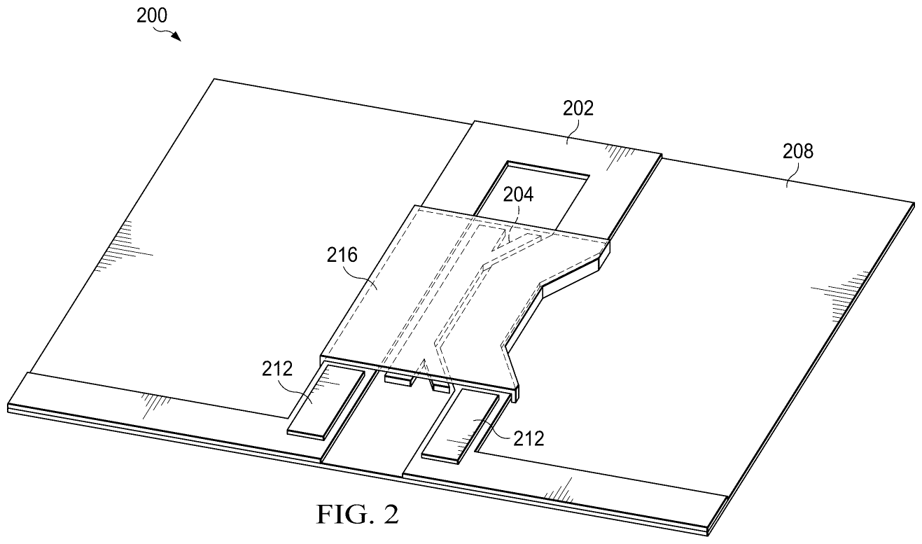

The illustrative embodiments provide a magnetoresistive device in which a generated magnetic field is focused by embedding an XMR channel in a ferromagnetic circuit. In one embodiment, a lamella of an XMR crystal is placed on top of a super-conductive gate electrode to generate magnetoresistive coupling (see FIG. 1). In another embodiment, gate electrode geometry is optimized, and a magnetoresistive active channel is grown between portions of the gate electrode instead of being placed over the gate electrode with a top-down approach (see FIG. 2).

The resistance of the XMR crystal is a function of the gate current through the magnetic field. This structure produces a significant (>10×) enhancement of magnetic field generation at the XMR channel and subsequent enhancement of amplifier gain.

FIG. 1 depicts a generalized magnetoresistive transistor illustrating the operating principles of the illustrative embodiments. Device 100 comprises a superconductive gate electrode 102. Current flows through superconductive gate electrode 102 between electrodes 104 (I_{G}+) and 106 (I_{G}−). As current flows through superconductive gate electrode 102 it generates a magnetic field B(I_{G}) around the gate electrode, represented by arrows 108.

Superconductive gate electrode 102 is placed on ferromagnetic material 110. A gap 116 is formed in the ferromagnetic loop comprising ferromagnetic material 110 and 112 that surrounds superconductive gate electrode 102. This gap 116 is filled with XMR material 114.

The magnetic field B(I_{G}) represented by arrows 108 flows around the superconductive gate electrode 102, preferentially through the ferromagnetic material 110, 112 that forms the ferromagnetic loop. The resistance of the XMR material 114 is a function of the gate current I_{G} through the magnetic field B(I_{G}) and changes its electrical resistance depending on the magnetic field applied to it. The higher B(I_{G}), the higher the magnetoresistance of the XMR material 114.

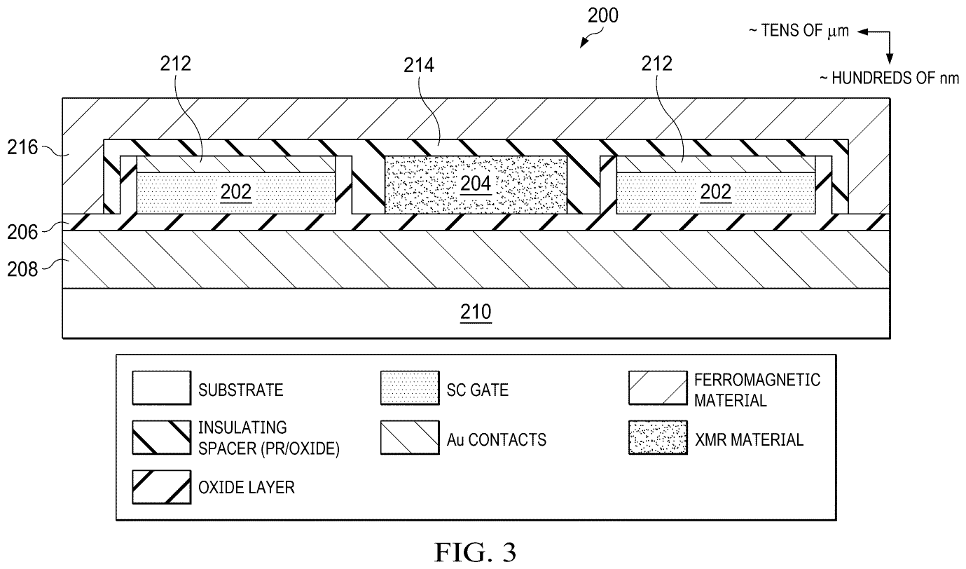

FIG. 2 depicts a top perspective view of a magnetoresistive device in accordance with an illustrative embodiment. FIG. 3 depicts a cross-section view of the magneto resistive device. Magnetoresistive device 200 is an example implementation of the principles underlying the operation of device 100 in FIG. 1.

Magnetoresistive device 200 comprises double gate configuration in which a superconductive gate electrode 202 wraps around and flanks an XMR active channel 204, thereby forming two gate portions on either side of the XMR active channel 204. The superconductive gate electrode 202 and XMR active channel 204 are formed on an oxide layer 206. The oxide layer 206 is formed on a ferromagnetic buried layer 208 which is formed on a substrate 210. Gold contacts 212 are formed on top of the superconductive gate electrode 202. An insulating spacer (e.g., photoresistor or oxide) electrically separates the superconductive gate electrode 202, gold contacts 212, and XMR active channel 204 from a ferromagnetic cap 216.

The double gate configuration in this embodiment optimizes the magnetic field generation. (Other configurations are possible.) By placing the superconductive gate electrode 202 on both sides of the XMR active channel 204, the configuration of magnetoresistive device 200 leverages the field generation from both sides, enabling a doubling of the signal. The optimized geometry of magnetoresistive device 200 can generate and focus a magnetic field of ˜10 mT in strength, which is a high value for an on-chip generated field. Such a field strength value enables the magnetoresistive device 200 to operate efficiently as a transconductance amplifier.

The ferromagnetic cap 216 closes the magnetic loop around the XMR active channel 204 and superconductive gate electrode 202. An insulating spacer 214 electrically isolates the XMR active channel 204 from the superconductive gate electrode 202 as well as electrically isolating the XMR active channel 204 and superconductive gate electrode 202 from the ferromagnetic cap 216. Insulating spacer 214 might comprise, e.g., an oxide or a photoresist material. In principle, an oxide provides better insulation, but for fabrication convenience, photoresist materials are a viable option.

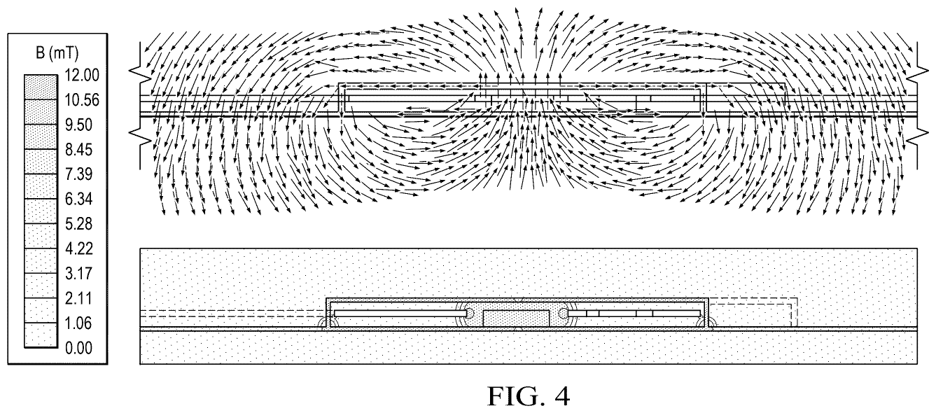

FIG. 4 depicts a diagram illustrating magnetic field focusing in accordance with an illustrative embodiment. FIG. 4 illustrates the behavior of the magnetic field produced by the double gate configuration cross-section shown in FIG. 3. Local field focusing as demonstrated in FIG. 4 can be applied to several domains such as, e.g., optics, sensors, etc. For example, in the optics domain there are materials whose optical properties are tuned with a magnetic field. The magnitude required for such tuning is typically too high to be generated locally. The focusing effect generated by the illustrative embodiments overcomes this limitation by producing the necessary local magnetic field locally.

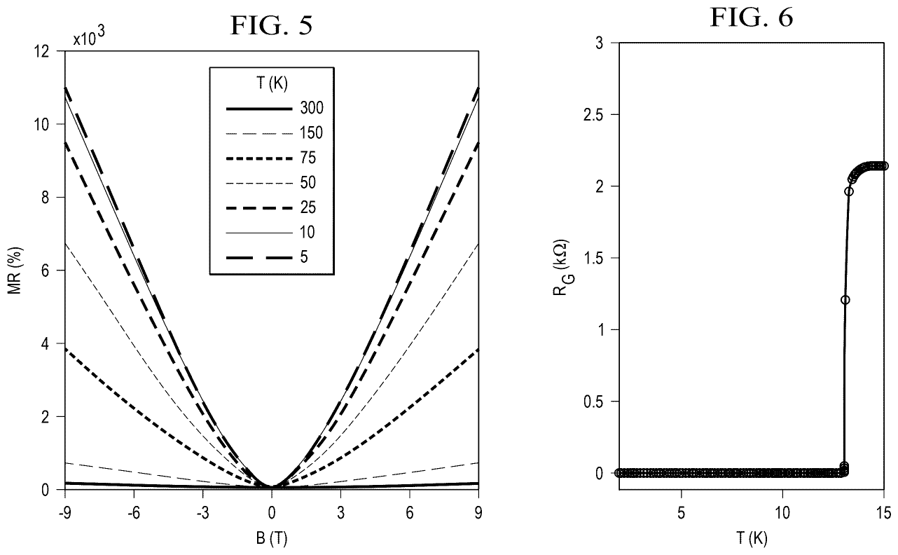

FIG. 5 depicts a graph of magnetoresistance versus magnetic field strength for different temperatures with which the illustrative embodiments may be implemented. The lower the temperature, the higher the magnetoresistance. The material used for the active channel, such as active channel 204 is an XMR material, such as, e.g., NbP (niobium phosphide). Other examples of possible XMR materials include Weyl or Dirac semimetals such as WP and WP2, graphene, molybdenum phosphide (MoP), tantalum arsenide (TaAs), cadmium arsenide (Cd3As2), etc.

FIG. 6 depicts a graph illustrating resistance versus temperature for a superconductive material with which the illustrative embodiments may be implemented. The example graph shown in FIG. 6 is for NbN (niobium nitride). Using a superconductive material for the gate electrode, such as gate electrode 202 avoids Joule heating, which is the process by which the passage of an electric current through a conductor produces heat and energy loss. This phenomenon occurs due to the resistance that the conductor offers to the flow of electric current.

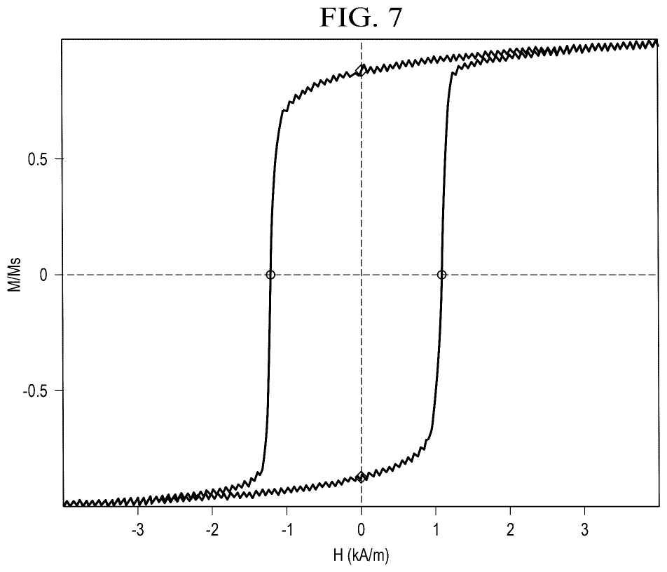

FIG. 7 depicts a hysteresis graph of a ferromagnetic material with which the illustrative embodiments may be implemented. Hysteresis loss is the energy loss that occurs in a magnetic material due to the process of magnetization and demagnetization. This phenomenon is observed in materials that are subjected to an alternating magnetic field. The loss arises because of the lag between the changes in the magnetizing force and the resultant magnetization of the material. To ensure low hysteresis loss, the illustrative embodiments employ a soft ferromagnetic material for the ferromagnetic buried layer 208 and ferromagnetic cap 216. In an embodiment, the preferred soft ferromagnetic material is Fe45Ni55 (nickel ferrite).

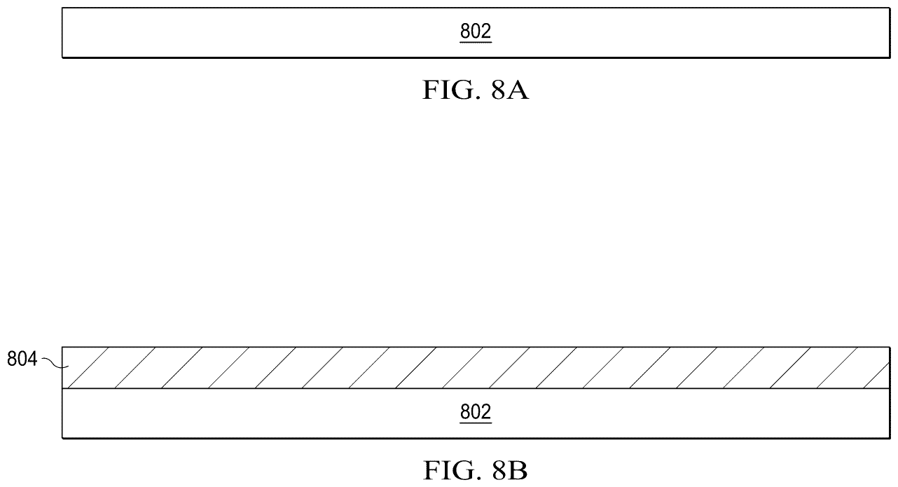

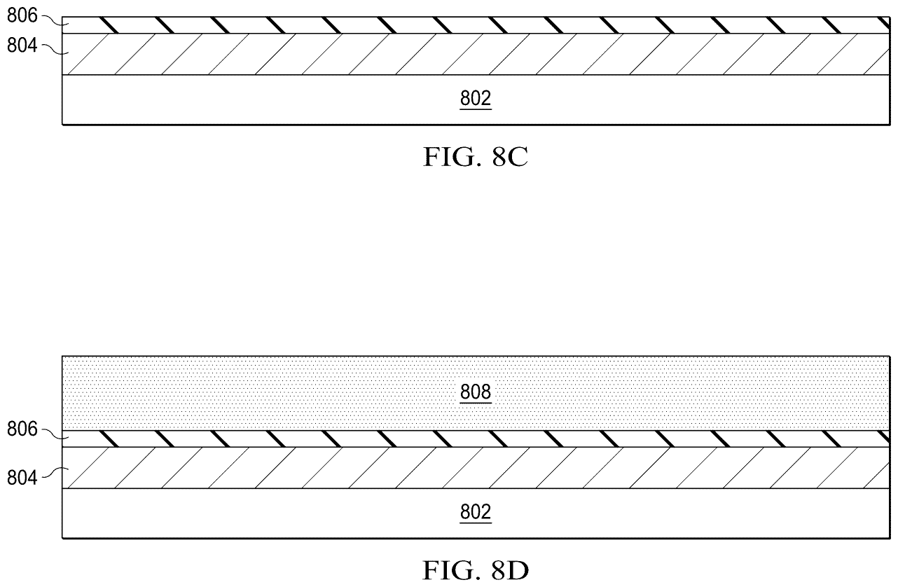

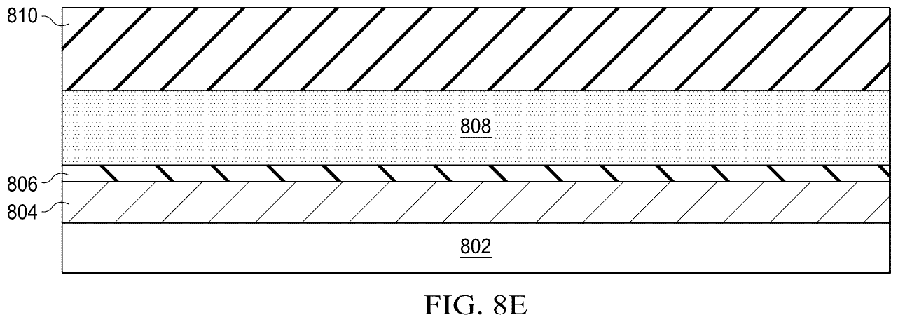

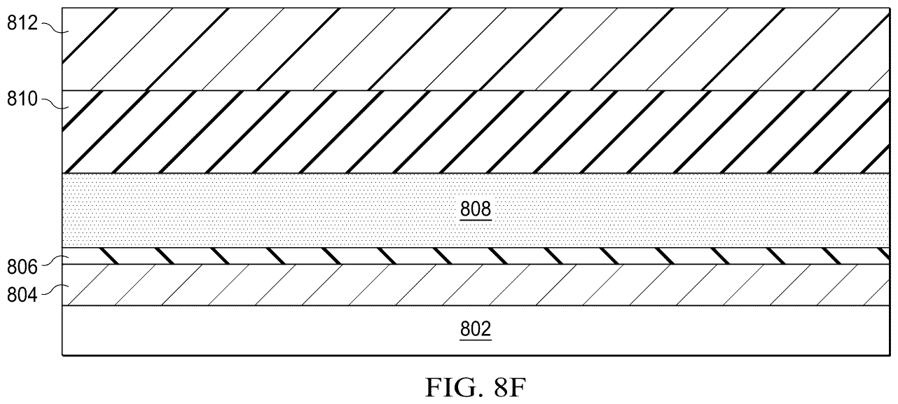

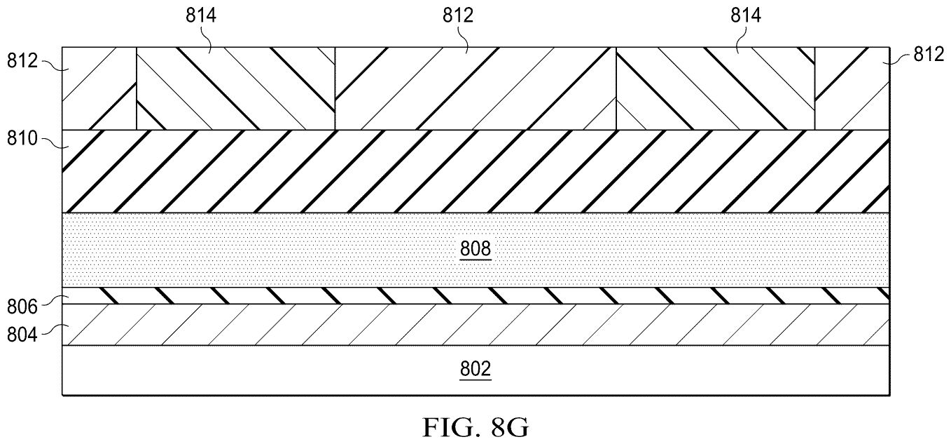

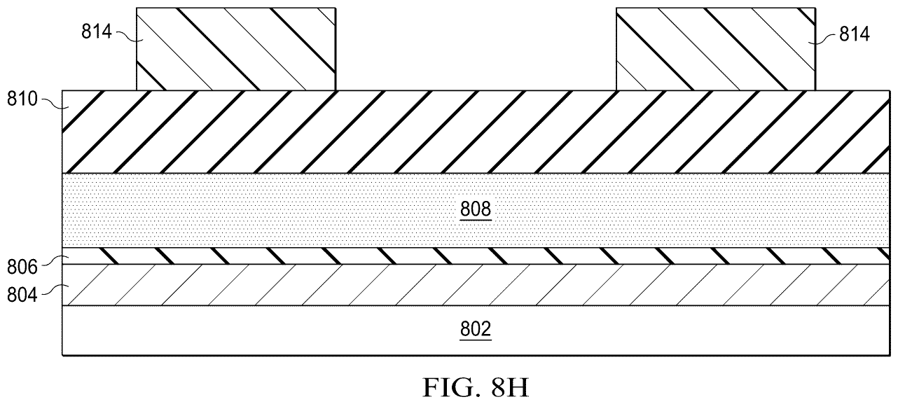

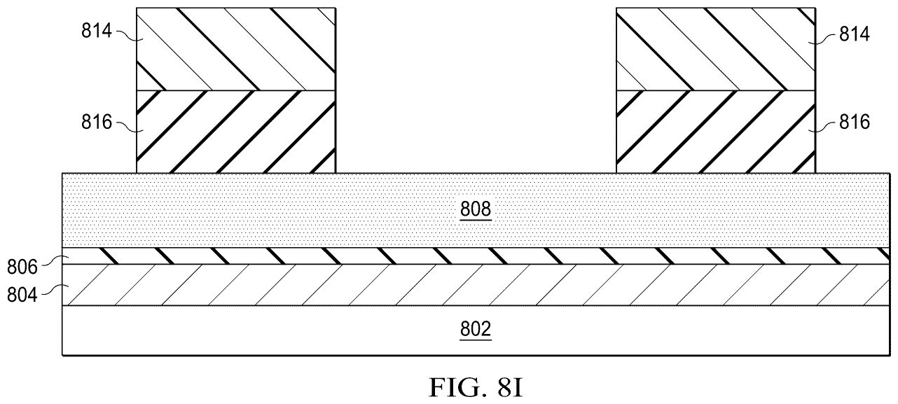

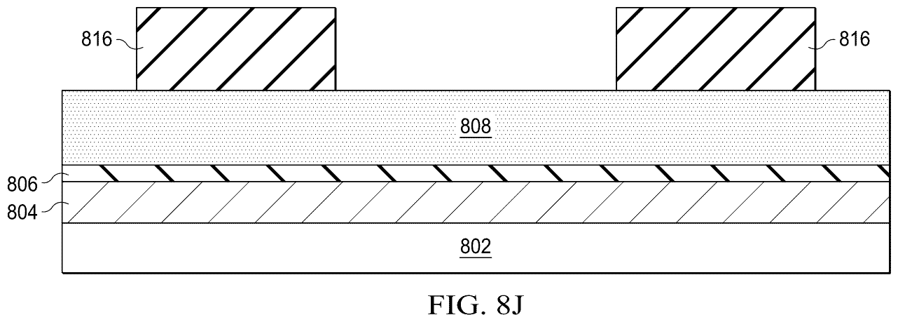

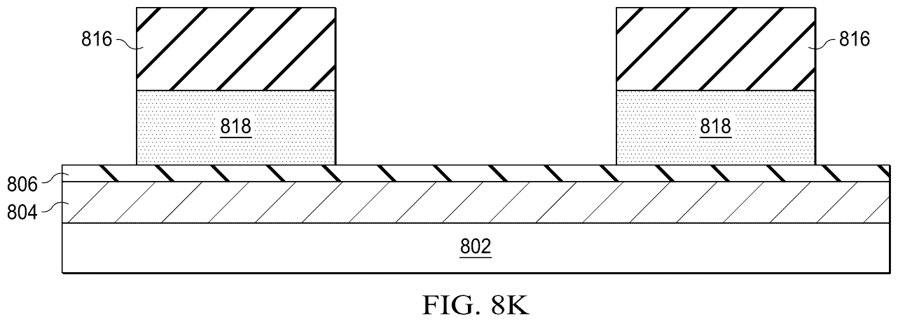

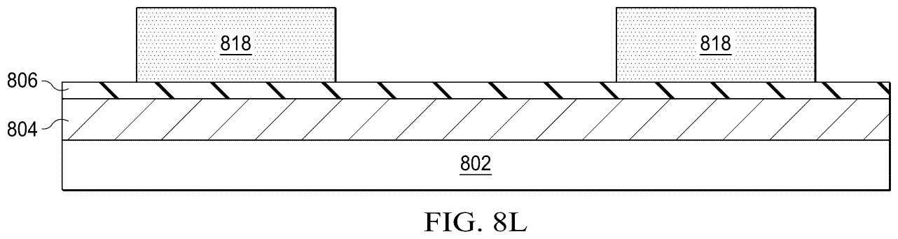

FIGS. 8A-10H depict a sequence of fabrication steps for magnetoresistive device 200 in accordance with an illustrative embodiment.

FIGS. 8A-8L illustrate the deposition of the substrate and superconductive gate electrode and the patterning of the superconductive gate electrode. FIG. 8A illustrates a Si (silicon) substrate layer 802. FIG. 8B illustrates the deposition of a ferromagnetic layer 804 on top of the substrate layer 802.

A SiN (silicon nitride) insulating layer 806 is then deposited over the buried layer 804 as shown in FIG. 8C. In FIG. 8D, a NbN superconductive layer 808 is deposited over the SiN insulating layer 806. A SiO₂ (silicon oxide) layer 810 is then deposited over the superconductive layer 808 as shown in FIG. 8E.

In FIG. 8F photoresist layer 812 for lithographic processing is deposited over the SiO2 layer 810. After exposure to an energy source, cross-linked portions 814 are formed within the photoresist layer 812 according to lithographic mask, as shown in FIG. 8G. In FIG. 8H the non-cross-linked portions of the photoresist layer 812 are removed, leaving only the cross-linked portions 814. The cross-linked portions 814 are then used as a mask to etch the SiO₂ layer 810, leaving only the masked portions 816 of SiO₂ underneath the cross-linked portions 814 of photoresist material, as shown in FIG. 8I.

In FIG. 8J the cross-linked portions 814 of photoresist material are removed, leaving the masked portions 816 of SiO2, which are then used as a hard mask to etch the superconductive layer 808, as shown in FIG. 8K. In FIG. 8L the remaining portions of SiO₂ are removed, leaving the NbN superconductive double gate electrode 818.

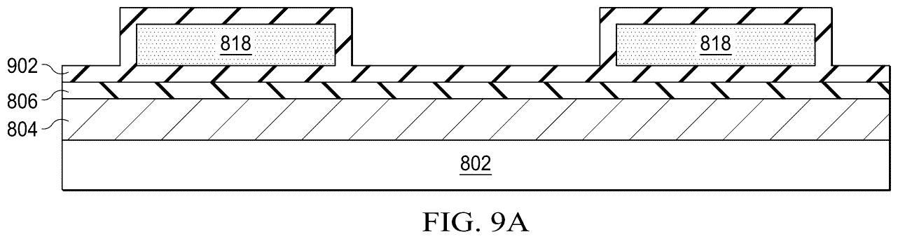

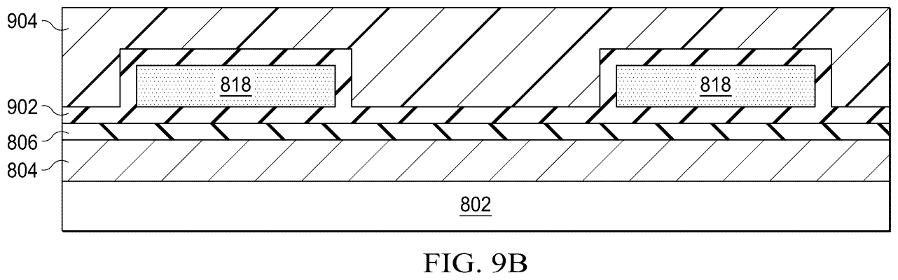

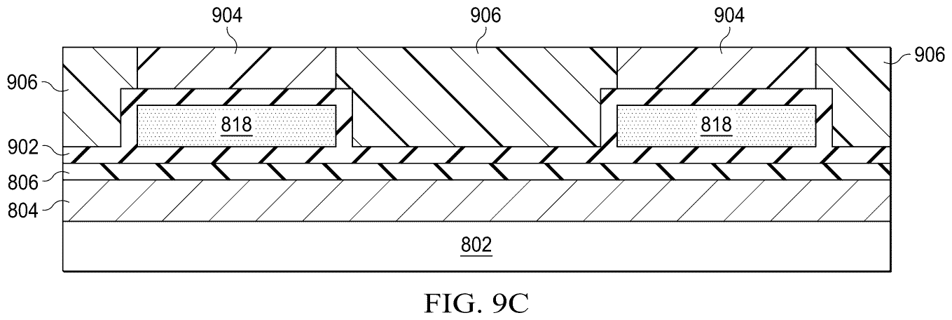

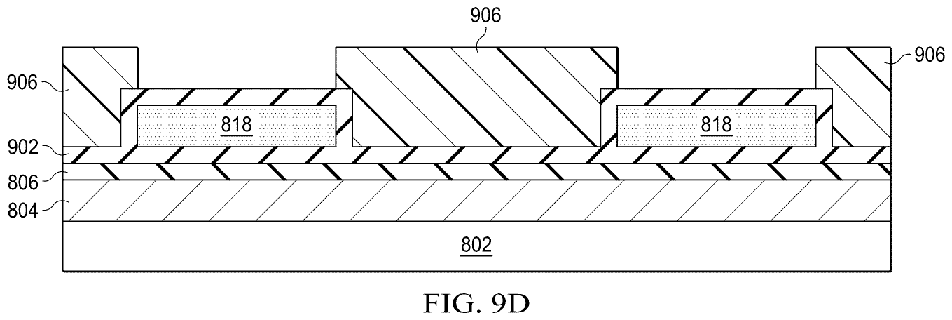

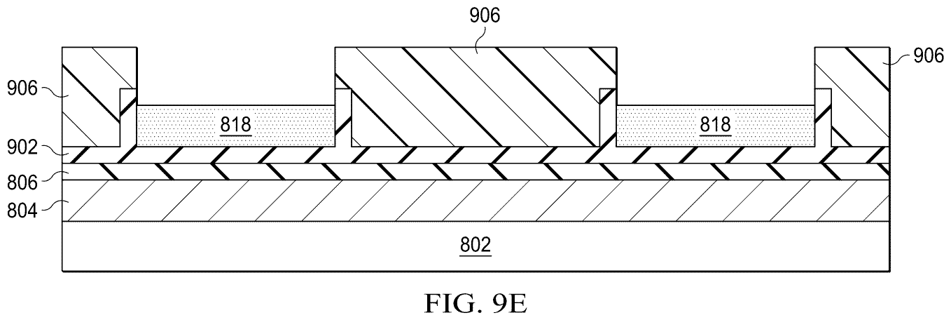

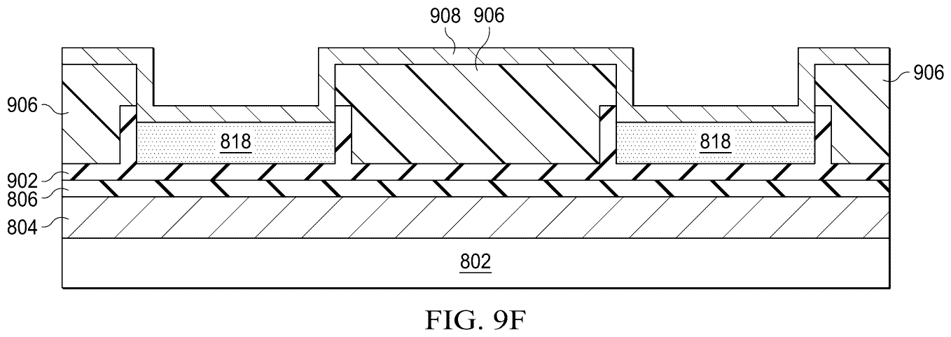

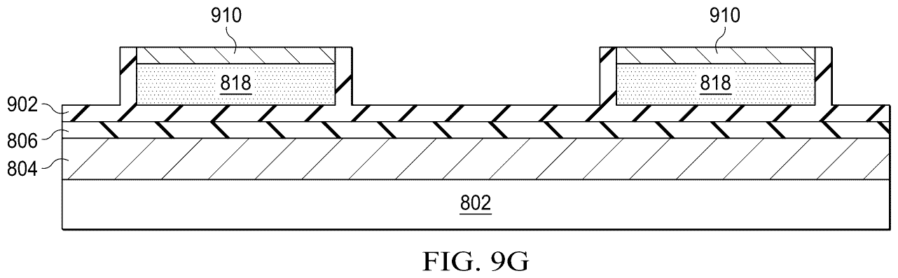

FIGS. 9A-9G illustrate the deposition and patterning of the gold contacts onto the superconductive double gate electrode. In FIG. 9A a new SiO₂ insulating coating 902 is deposited over superconductive double gate electrode 818 and SiN insulating layer 806.

In FIG. 9B a new photoresist layer 904 is then deposited over the SiO₂ insulating coating 902 and exposed to an energy source that produces cross-linked sections 906 of photoresist material as shown in FIG. 9C. In this stage of fabrication, a different lithographic mask is used than for the step shown in FIG. 8G. Whereas in FIG. 8G the cross-linked portions 814 of photoresist material are formed over the sections of NbN that eventually form the double gate electrode 818, in FIG. 9C, the opposite pattern occurs wherein the sections of photoresist material directly over the double gate electrode 818 are the ones that do not become cross-linked.

In FIG. 9D the non-cross-linked sections of photoresist material are removed, and then in FIG. 9E the SiO2 insulating coating directly above the double gate electrode is removed, leaving the double gate electrode structure exposed in contact areas.

Gold 908 is then deposited over the structure as shown in FIG. 9F. In FIG. 9G the cross-linked photoresist material is removed along with the gold that is not directly on top of the double gate electrode's contacts, leaving the double gate electrode with gold contacts 910.

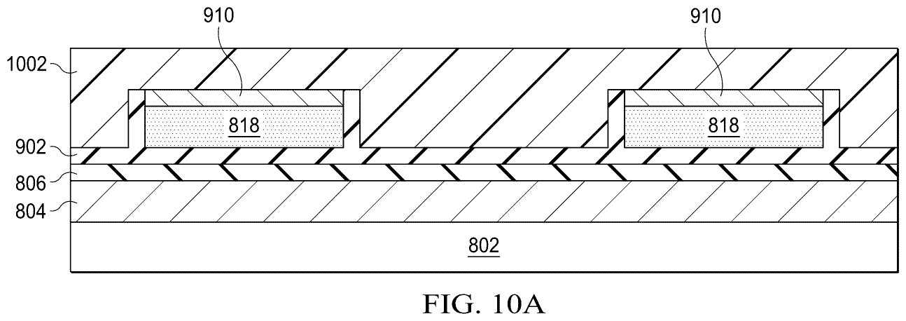

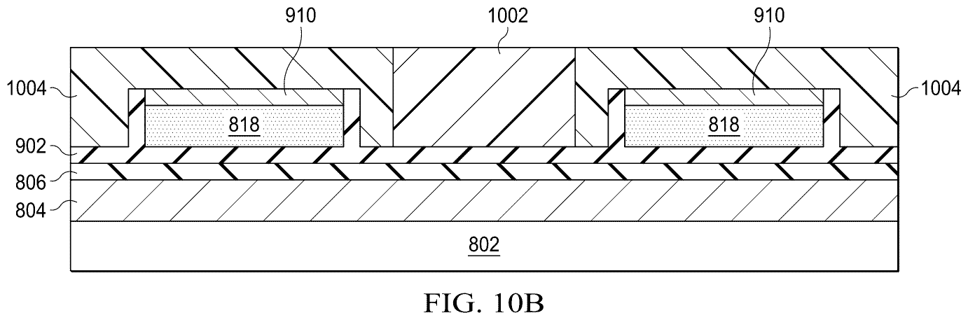

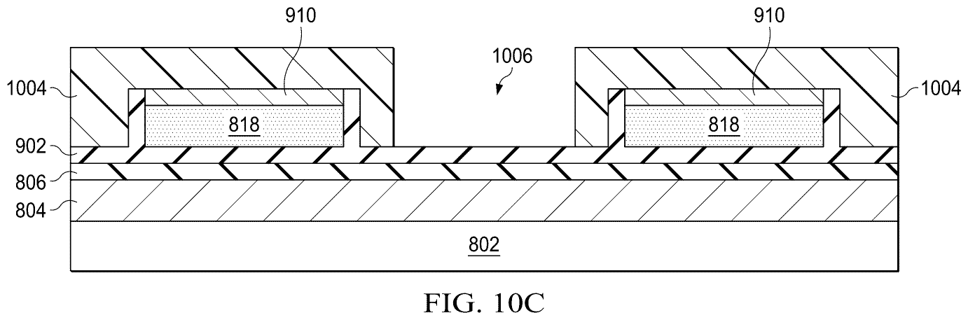

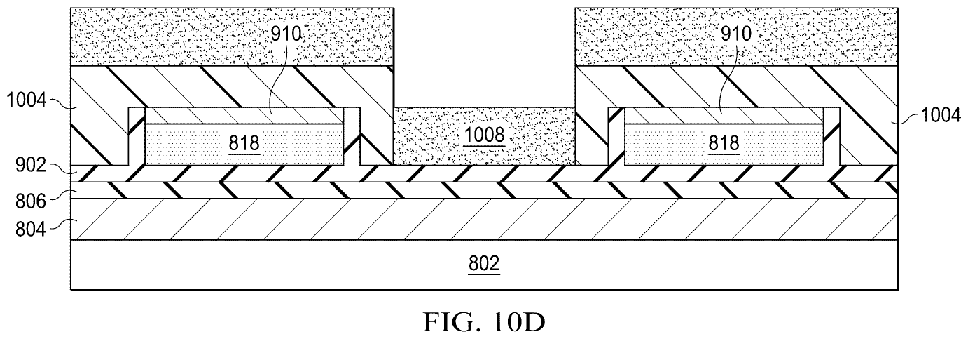

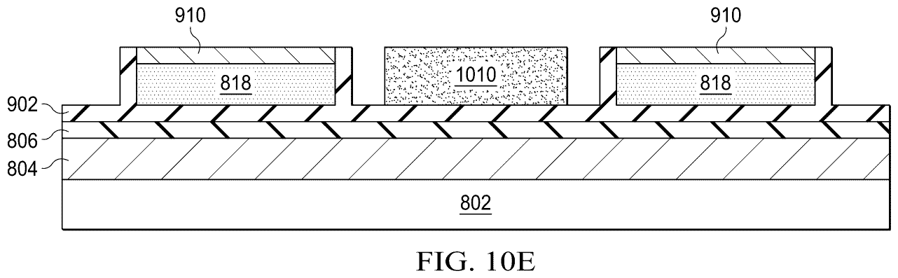

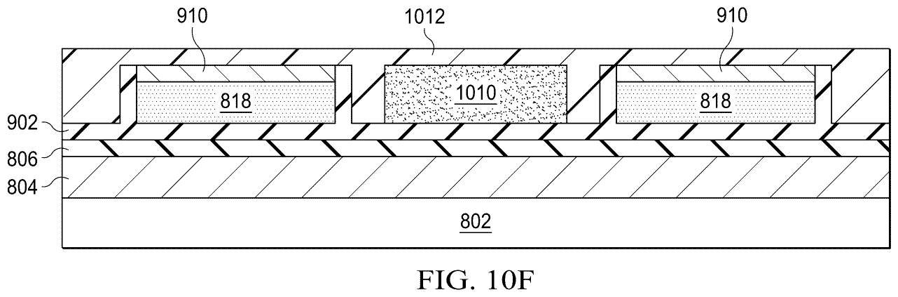

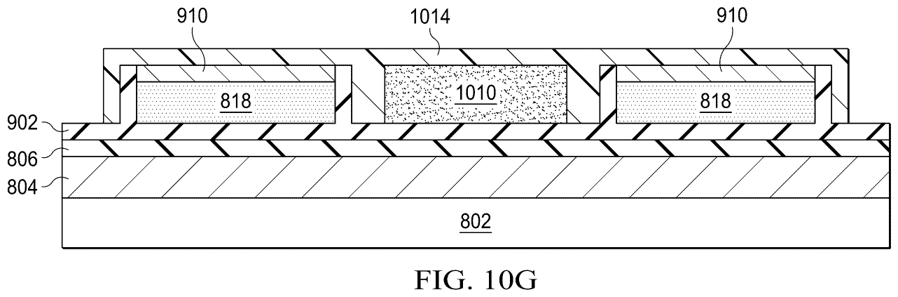

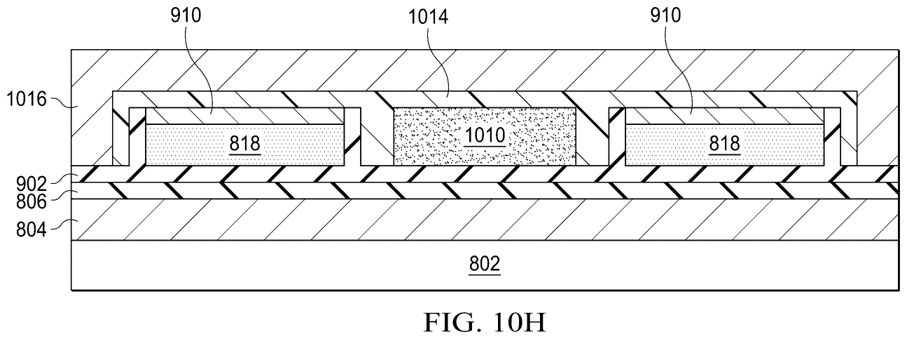

FIGS. 10A-10L illustrate the deposition of the active channel and cap. In FIG. 10A a new photoresist layer 1002 is deposited over the gold contacts and SiO₂ insulating coating. The photoresist layer 1002 is exposed to an energy using a lithographic mask that prevents a central section 1004 of the photoresist material from cross-linking as shown in FIG. 10B. This non-cross-linked central section of photoresist material is then removed, leaving a central channel 1006 between the double gate electrode as shown in FIG. 10C.

In FIG. 10D XMR material 1008 is deposited over the structure. The XMR material 1008 might comprise NbP. The XMR material over the cross-linked photoresist material is then removed along with the cross-linked photoresist material, leaving the central active channel 1010 of XMR material between the double gate electrode structure as shown in FIG. 10E.

In FIG. 10F, a new photoresist layer 1012 is deposited over the structure and is exposed in its entirety to an energy source encasing the superconductive double gate electrode and XMR active channel to provide electrical insulation as shown in FIG. 10G. As explained above, an oxide might also be used as an alternative to photoresist material.

Finally, as shown in FIG. 10H, a ferromagnetic cap 1016 is added. The cross-linked photoresist layer 1014 acts as an insulating layer between the ferromagnetic cap 1016 and the superconductive double gate electrode, and XMR active channel and prevents shorting within the circuit. Alternatively, any nonconductive material such as an oxide can be used to form layer 1014 as a spacer.

As used herein, “a number of” when used with reference to items, means one or more items. For example, “a number of parameters” is one or more parameters. As another example, “a number of operations” is one or more operations.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combination of these items can be present. In some illustrative examples, “at least one of” can be, for example, without limitation, two of item A; one of item B; and ten of item C; four of item B and seven of item C; or other suitable combinations.

The description of the different illustrative embodiments has been presented for purposes of illustration and description and is not intended to be exhaustive or limited to the embodiments in the form disclosed. The different illustrative examples describe components that perform actions or operations. In an illustrative embodiment, a component can be configured to perform the action or operation described. For example, the component can have a configuration or design for a structure that provides the component an ability to perform the action or operation that is described in the illustrative examples as being performed by the component. Further, to the extent that terms “includes”, “including”, “has”, “contains”, and variants thereof are used herein, such terms are intended to be inclusive in a manner similar to the term “comprises” as an open transition word without precluding any additional or other elements.

The descriptions of the various embodiments of the present invention have been presented for purposes of illustration, but are not intended to be exhaustive or limited to the embodiments disclosed. Not all embodiments will include all of the features described in the illustrative examples. Further, different illustrative embodiments may provide different features as compared to other illustrative embodiments. Many modifications and variations will be apparent to those of ordinary skill in the art without departing from the scope and spirit of the described embodiment. The terminology used herein was chosen to best explain the principles of the embodiment, the practical application or technical improvement over technologies found in the marketplace, or to enable others of ordinary skill in the art to understand the embodiments disclosed here.

What is claimed is:

1. A magnetoresistive device, comprising:
an active channel comprising an extremely large magnetoresistance (XMR) material;
a gate electrode surrounding the active channel, wherein the gate electrode has a first portion on one side of the active channel and a second portion on an opposite side of the active channel; and
an insulating spacer that electrically isolates the active channel from the gate electrode.

2. The magnetoresistive device of claim 1, further comprising:
a ferromagnetic buried layer under the active channel and gate electrode;
an insulating layer that electrically isolates the ferromagnetic buried layer from the active channel and gate electrode; and
a ferromagnetic cap over the active channel and gate electrode, wherein the ferromagnetic cap and ferromagnetic buried layer form a ferromagnetic loop around the gate electrode.

3. The magnetoresistive device of claim 1, wherein the gate electrode comprises a superconductive material.

4. The magnetoresistive device of claim 3, wherein the superconductive material comprises niobium nitride.

5. The magnetoresistive device of claim 1, wherein the XMR material comprises a Weyl or Dirac semimetal.

6. The magnetoresistive device of claim 5, wherein the Weyl or Dirac semimetal comprises one of:
niobium phosphide;
graphene;
molybdenum phosphide (MoP);
tantalum arsenide (TaAs); or
cadmium arsenide (Cd3As2).

7. The magnetoresistive device of claim 1, wherein the gate electrode wraps around the active channel in a common plane to form a double gate configuration flanking the active channel.

8. A magnetoresistive device, comprising:
a superconductive gate electrode folded into a double gate configuration within a plane;
an extremely large magnetoresistance (XMR) channel positioned in the plane between a first portion and a second portion of the double gate configuration; and
a ferromagnetic loop comprising a ferromagnetic buried layer under the superconductive gate electrode and XMR channel and a ferromagnetic cap over the superconductive gate electrode and XMR channel.

9. The magnetoresistive device of claim 8, further comprising an insulating spacer that electrically isolates the superconductive gate electrode, XMR channel, and ferromagnetic cap from each other.

10. The magnetoresistive device of claim 8, wherein the gate electrode comprises niobium nitride.

11. The magnetoresistive device of claim 8, wherein the XMR channel comprises a Weyl or Dirac semimetal.

12. The magnetoresistive device of claim 11, wherein the Weyl or Dirac semimetal comprises one of:
niobium phosphide;
graphene;
molybdenum phosphide (MoP);
tantalum arsenide (TaAs); or
cadmium arsenide (Cd3As2).

13. A magnetoresistive device, comprising:
a gate electrode;
an extremely large magnetoresistance (XMR) channel proximal to the gate electrode; and
a ferromagnetic loop that surrounds the gate electrode.

14. The magnetoresistive device of claim 13, wherein the gate electrode comprises a superconductive material.

15. The magnetoresistive device of claim 14, wherein the superconductive material comprises niobium nitride.

16. The magnetoresistive device of claim 13, wherein the XMR material comprises a Weyl or Dirac semimetal.

17. The magnetoresistive device of claim 16, wherein the Weyl or Dirac semimetal comprises one of:
niobium phosphide;
graphene;
molybdenum phosphide (MoP);
tantalum arsenide (TaAs); or
cadmium arsenide (Cd3As2).

18. The magnetoresistive device of claim 13, wherein the gate electrode wraps around the XMR channel in a common plane to form a double gate configuration flanking the XMR channel.

19. The magnetoresistive device of claim 13, wherein the ferromagnetic loop comprises a ferromagnetic buried layer under the gate electrode and a ferromagnetic cap over the gate electrode.

20. The magnetoresistive device of claim 19, wherein the XMR channel fills a gap in the ferromagnetic cap.
